(19) United States
(12) Patent Application Publication
(10) Pub. No.: US 2013/0299744 A1
(43) Pub. Date: Nov. 14, 2013

(54) METAL COMPLEXES HAVING ADAPTABLE EMISSION COLORS FOR OPTOELECTRONIC DEVICES

(71) Applicants: Hartmut Yersin, Sinzing (DE); Rafal Czerwieniec, Regensburg (DE); Uwe Monkowius, Linz (AT); Thomas Baumann, Karlsruhe (DE)

(72) Inventors: Hartmut Yersin, Sinzing (DE); Rafal Czerwieniec, Regensburg (DE); Uwe Monkowius, Linz (AT); Thomas Baumann, Karlsruhe (DE)

(73) Assignee: CYNORA GMBH, Eggenstein-Leopoldshafen (DE)

(21) Appl. No.: 13/981,111

(22) PCT Filed: Jan. 23, 2012
(86) PCT No.: PCT/EP12/50989

§ 371 Date: Jul. 23, 2013

(30) Foreign Application Priority Data
Jan. 23, 2011 (DE) 102011000282.0
Jan. 30, 2011 (DE) 102011000406.8

(51) Int. Cl. H01L 51/00

(52) U.S. Cl. CPC H01L 51/0091
USPC 252/301.35; 548/101; 546/2

(57) ABSTRACT

The invention relates to a method for increasing the Stokes shift of an emitting metal complex having a given geometry in the region of the metal center in the electronic ground state, wherein said geometry is changing as a result of an optical excitation or an excitation by a hole-electron recombination, and to a polymeric matrix by means of which it is possible to influence the change in geometry in the excited state.

The invention relates to the use of mononuclear or binuclear metal complexes having adaptable emission colors as emitters, especially in OLEDs (organic light emitting diodes) and in other optoelectronic devices.

### INTRODUCTION

Currently new processes win recognition in the field of visual display and lighting technology. It will be possible to manufacture flat displays or illuminated surfaces having a thickness of less than 0.5 mm. These are notable for many fascinating properties. For example, it will be possible to achieve illuminated surfaces in the form of wallpaper with very low energy consumption. It is also of particular interest that color visual display units will be producible with hitherto unachievable colorfastness, brightness and viewing angle independence, with low weight and with very low power consumption. It will be possible to configure the visual display units as micro-displays or large visual display units of several square meters in area in rigid form or flexibly, or else as transmission or reflection displays. In addition, it will be possible to use simple and cost-saving production processes such as screen printing or inkjet printing. This will enable very inexpensive manufacture compared to conventional flat visual display units. This new technology is based on the principle of the OLEDs, the organic light-emitting diodes. Furthermore, through the use of specific organometallic materials (molecules), many new optoelectronic applications are on the horizon, for example in the field of organic solar cells, organic field-effect transistors, organic photodiodes, etc.

Particularly for the OLED sector, it is apparent that such devices are already now of economic significance, since mass production is expected shortly. Such OLEDs consist predominantly of organic layers, which can also be manufactured flexibly and inexpensively. OLED components can also be configured with large areas as illumination bodies, but also in small form as pixels for displays.

Compared to conventional technologies, for instance liquid-crystal displays (LCDs), plasma displays or cathode ray tubes (CRTs), OLEDs have numerous advantages, such as a low operating voltage of a few volts, a thin structure of only a few hundred nm, high-efficiency self-illuminating pixels, high contrast and good resolution, and the possibility of representing all colors. In addition, in an OLED, light is produced directly on application of electrical voltage, rather than merely being modulated.

A review of the function of OLEDs can be found, for example, in H. Yersin, Top. Curr. Chem. 2004, 241, 1 and H. Yersin, “Highly Efficient OLEDs with Phosphorescent Materials”; Wiley-VCH, Weinheim, Germany, 2008.

Since the first reports regarding OLEDS (see, for example, Tang et al., Appl. Phys. Lett. 1987, 51, 913), these devices have been developed further particularly with regard to the emitter materials used, and particular interest has been attracted in the last few years by what are called triplet emitters or else phosphorescent emitters.

OLEDs are generally implemented in layer structures. For better understanding, FIG. 1 shows a basic structure of an OLED. Owing to the application of external voltage to a transparent indium tin oxide (ITO) anode and a thin metal cathode, the anode injects positive holes, and the cathode negative electrons. These differently charged charge carriers pass through intermediate layers, which may also consist of hole or electron blocking layers not shown here, into the emission layer. The oppositely charged charge carriers meet therein at or close to doped emitter molecules, and recombine. The emitter molecules are generally incorporated into matrix molecules or polymer matrices (in, for example, 2 to 20% by weight), the matrix materials being selected so as also to enable hole and electron transport. As described below, matrix selection is of particular importance within the scope of this invention. The recombination gives rise to excitons (=excited states), which transfer their excess energy to the respective electroluminescent compound. This compound can then be converted to a particular electronic excited state, which is then converted very substantially and with substantial avoidance of radiationless deactivation processes to the corresponding ground state by emission of light.

With a few exceptions, the electronic excited state, which can also be formed by energy transfer from a suitable precursor exciton, is either a singlet or triplet state, consisting of three sub-states. Since the two states are generally occupied in a ratio of 1:3 on the basis of spin statistics, the result is that the emission from the singlet state, which is referred to as fluorescence, leads to maximum emission of only 25% of the excitons produced. In contrast, triplet emission, which is referred to as phosphorescence, exploits and converts all excitons and emits them as light (triplet harvesting) such that the internal quantum yield in this case can reach the value of 100%, provided that the additionally excited singlet state, which is above the triplet state in terms of energy, relaxes fully to the triplet state (intersystem crossing, ISC), and radiationless competing processes remain insignificant. Thus, triplet emitters, according to the current state of the art, are more efficient electroluminophores and are better suitable for ensuring a high light yield in an organic light-emitting diode.

The triplet emitters suitable for triplet harvesting used are generally transition metal complexes in which the metal is selected from the third period of the transition metals. This predominantly involves very expensive noble metals such as iridium or platinum. (See also H. Yersin, Top. Curr. Chem. 2004, 241, 1 and M. A. Baldo, D. F. O'Brien, M. E. Thompson, S. R. Forrest, Phys. Rev. B 1999, 60, 14422). The prime reason for this is the high spin-orbit-coupling (SOC) of noble metal central ions (SOC constants Ir(III): 4000 cm⁻¹; Pt(II): ≈4500 cm⁻¹; Ref.: S. L. Murov, J. Carmicheal, G. L. Hug, Handbook of Photochemistry, 2nd Edition, Marcel Dekker, New York 1993, p. 338 ff). Due to this quantum mechanical characteristic, the triplet-singlet transition, which is without SOC strictly forbidden for optical transitions, is allowed and an emission decay time of a few μs, small enough for OLED applications, is achieved.

Economically, it would be advantageous to replace the expensive noble metals with less expensive metals. Moreover, a large number of OLED emitter materials known to date are ecologically problematic, so that the use of less toxic materials is desirable. Copper(I) complexes, silver(I) complexes and gold(I) complexes are to be considered for this, for example. However, regarding such central ions, especially Cu(I) and Ag(I) have much smaller SOC values (SOC constants of Cu(I): ≈850 cm⁻¹, Ag(I): ≈1780 cm⁻¹, Au(I): ≈5100 cm⁻¹; Ref.: S. L. Murov, J. Carmicheal, G. L. Hug, Handbook of Photochemistry, 2nd Edition, Marcel Dekker, New York 1993, p. 338 ff), than the central ions mentioned above. Therefore, the very important triplet-singlet-transitions of Cu(I)-complexes and Ag(I)-complexes respectively would be relatively strongly forbidden, and emission lifetimes, which are in the range of a few 100 us to ms, would be too long for use in OLEDs. Such high emission decay times give rise to saturation effects with increasing current densities and the resulting occupation of a majority of or all emitter molecules. Consequently, further charge carrier streams can no longer lead completely to the occupation of the excited and emitting states. The result is then more unwanted ohmic losses. This leads to a distinct decline in efficiency of the OLED device with rising current density (called “roll-off” behavior). The effects of triplet-triplet annihilation and of self-quenching are similarly unfavorable (see, for example, H. Yersin, “Highly Efficient OLEDs with Phosphorescent Materials”, Wiley-VCH, Weinheim 2008 and S. R. Forrest et al., Phys. Rev. B 2008, 77, 235215). For instance, disadvantages are found particularly in the case of use of such emitters for OLED illuminations where a high luminance, for example of more than 1000 cd/m², is required (cf.: J. Kido et al. Jap. J. Appl. Phys. 2007, 46, L10.). Furthermore, molecules in electronically excited states are frequently more chemically reactive than in ground states so that the likelihood of unwanted chemical reactions increases with the length of the emission lifetime. The occurrence of such unwanted chemical reactions has a negative effect on the lifetime of the device. One important disadvantage is also that with long emission lifetime and the small radiative emission rate related to this, radiationless processes mostly predominate. This results in undesirably low emission quantum yields.

Moreover the emitter materials generally have their respective fixed emission colors. That way specific demands regarding emission colors cannot be met in many cases. Of particular technological importance is, for example, the realization of white-light emitters. In order to realize white-light emitters a very broad color spectrum, superimposed from different primary colors, has to be generated. Also in this area there is a deficit in the previously available materials.

The object of this invention is the adaptation of the emission colors of certain emitters.

### SHORT DESCRIPTION OF THE INVENTION

In a first aspect the invention relates to a method for shifting the emission wavelength of a metal complex emitting at a given wavelength to wavelengths greater than the given wavelength. In other words, the invention relates to a method for increasing the Stokes shift of an emitting metal complex.

The Stokes shift of an emitting metal complex is the difference in wavelength between the lowest energy absorption (absorption peak with lowest energy) and the main maximum of emission (emission peak). The Stokes shift refers, for example, to the absorption from the singlet ground state to the lowest excited singlet state and to the emission from this excited singlet state to the singlet ground state.

This method makes use of at least one metal complex having the following properties: The metal complex has in the region of the metal center a given geometry in the electronic ground state and seeks a changed geometry in the electronically excited state. The change in geometry is depending on the environment of the emitting complex, in particular on the surrounding polymeric matrix.

According to the invention, the method comprises the step of embedding the metal complex in a polymeric matrix. The polymeric matrix has to be in this case such that the change in geometry of the embedded metal complex is possible, as soon as it is excited electronically. The electronic excitation can, for example, be carried out via optical photoexcitation or in an OLED via an excitation by a hole-electron recombination. The kind of geometry change is described further below.

The embedding of the metal complex in a polymeric matrix may be carried out according to any manner known in the art. It is possible to embed the metal complexes into an existing matrix. Alternatively, the metal complexes may be embedded in the matrix during the formation of the matrix, for example, from monomers of polymers. One-step reactions known to the person skilled in the art under the term “click-reactions” are preferred.

In one preferred embodiment of the invention, a reaction for the embedding of the metal complex in a polymeric matrix comprises the following steps. A mixture of a first reactant in form of an organic metal complex emitter and a second reactant in form of a polymer, i.e. a means for the immobilisation of the metal complex, is applied to a solid support. The metal complex is cross-linked into the forming multidimensional network during the performed autocatalyzed reaction of the first reactant with the second reactant. The formation of the cross-linking is carried out at higher temperature, preferably between 80° C. to 120° C. The application of a mixture of both reactants on a solid support can be carried out by all means known in the art, in particular by inkjet-printing, dipping, spin coating, slot-die coating or knife coating.

After application on a glass slide using a doctor blade apparatus (all other known printing or coating methods such as spin coating, slot-die coating or inkjet-printing, for example, are also possible) in a thin layer and curing by heating, this layer is stabilized and insoluble. Using this method, multilayer arrangements, which otherwise need orthogonal solvents or photochemical curing steps for implementation, can be easily realized. In addition, this crosslinking provides for a stabilisation and fixation of the geometric structure of the metal complexes, preventing a movement of the ligands and thus a change in structure of the excited molecules and effectively inhibiting a reduction in efficiency due to nonradiative relaxation pathways.

In a preferred embodiment of the invention, the first reactant and the second reactant comprise chemical groups, which make a fast and efficient covalent bonding of the reactants possible. These chemical groups are addressed here as anchor groups. Examples for such anchor groups are shown in FIG. 5. The first and the second anchor group respectively, which are complementary to each other, thus enabling an embedding (linking) of a metal complex, can be arranged either on the metal complex or on the unit forming the polymeric unit. The attachment of the anchor groups to the organic ligand of the metal complex can be carried out at any suitable position of the organic ligand of the metal complex, preferably not in position ortho to the atom coordinating to the metal center. Preferably, the metal complexes disclosed herein comprise at least one anchor group for embedding into the polymeric matrix.

With respect to the invention, such reactions are preferred which do not need the addition of another reactant besides the metal complex and the second reactant, i.e. reactions that need at the most a catalyst that does not interfere with the further use. Examples for such reactions are 1,3-bipolar cycloadditions, Diels-Alder reactions, nitrone-alkyne reactions, nitril oxide-alkyne reactions, thiol-ene reactions, thiol-yne reactions, thiol-isocyanite reactions, tetrazole-alkene reactions and other methods known as click reactions in literature. Reactions that are catalyzed by the metal itself contained in the metal complex are preferred, corresponding to an auto-catalyzed cross-linking.

In a second aspect, the invention relates to a composition, which a) comprises at least one emitting metal complex with a given geometry in the region of the metal center in electronic ground state, said geometry changing as a result of electronic excitation, and b) comprises a polymeric matrix. The metal complex is embedded in the polymeric matrix in such a way that the given geometry of the metal complex is changed by electronic excitation (such as light absorption or hole-electron recombination).

In preferred embodiments of the invention, the following applies to the method as well as to the composition described above:

In a preferred embodiment of the invention, the metal complex used has a ΔE(S₁−T₁)-value between the lowest excited singlet (S₁)-state and the triplet (T₁)-state below of smaller than 2500 cm⁻¹, preferably smaller than 1500 cm⁻¹, more preferably smaller than 1000 cm⁻¹, most preferably smaller than 500 cm⁻¹.

The emitting metal complex having a given geometry in the region of the metal center in the electronic ground state can be chosen from a group consisting of mononuclear metal complexes and binuclear metal complexes. In preferred embodiments of the invention, the metal complex is a copper complex, a gold complex or a silver complex. Preferably, the mononuclear metal complex is a complex according to formula I and the binuclear metal complex is a complex according to formula II, both of which are shown further below.

In preferred embodiments of this method, the change in given geometry due to electronic excitation is in particular the change of a tetrahedral coordination towards a square-planar coordination relating to a change with a tendency to planarization.

The electronically excited metal complex used in this method and present in the composition preferably has an emission lifetime of at the most 20 μs, preferably of at the most 10 μs. Furthermore, it is preferred that the electronically excited, geometrically hardly distorted metal complex, e.g. embedded in a relatively rigid crystalline form, exhibits an emission quantum yield of the solid of greater than 30%, preferably greater than 50%, particularly preferably greater than 70%.

By means of the method, the Stokes-shift can be increased by 10 nm, 50 nm, 100 nm or 150 nm by embedding the metal complex into a polymeric matrix, so that a composition is provided which comprises a metal complex emitter with a correspondingly changeable Stokes-shift.

Likewise, the emission spectrum of the metal complex can be broadened using this method by embedding the complex into a polymeric matrix, in particular by 10 nm to 100 nm.

An amorphous, soft polymer (e.g. polysiloxanes, polyethylene oxides), a medium-rigid (e.g. PMMA=polymethylmetacrylate, polycarbonates) or a very rigid polymer (e.g. polyphenylene oxides) can be used as a polymeric matrix. Rigidity can be significantly increased by the use of cross-linkable polymers, wherein the crosslinking can be initiated by thermal or UV activation or by use of auto-catalyzing emitter materials For example, the metal center present in the metal complex emitter can serve as catalyst, so that an auto-catalyzed crosslinking takes place. The appropriate degree of “hardness” and “softness” can, for example, also be achieved by annealing.

Through application of the method, a change of emission color of the metal complex can be achieved, wherein preferably a change to white light is also possible. A large Stokes-shift with a strong broadening is advantageous for this.

In comparison to the metal complex as solid, the composition leads to an emitter with changed color emission. Particularly preferred are compositions in which the embedded metal complex emits white light.

In a third aspect, the invention relates to optoelectronic devices comprising a composition as described herein.

In particular in OLEDs, the composition according to the invention in the emitting layer is given by the ratio of the mass of the metal complex and the mass of the matrix material of between 1 weight % to 99 weight %, wherein 2 weight % to 20 weight % are preferred.

In a fourth aspect, the invention relates to the use of a process as described herein or of a composition as described herein in an optoelectronic device.

The term opto-electronic device used herein refers to organic light emitting diodes (OLEDs), light-emitting electrochemical cells (LEECs or LECs), OLED-sensors, in particular gas and vapor sensors which are not hermetically screened from the outside, organic solar cells (OSCs), organic field-effect transistors, organic lasers, organic diodes, organic photo diodes and “down conversion” systems.

Accordingly, the invention relates to the creation and provision of compositions and the use thereof, wherein the compositions shows in particular the following properties:
relatively short emission lifetime of only a few μs,
high emission quantum yields of larger than 30%,
convertibility of emission colors,
convertibility of the width of the emission bands.

In a fifth aspect, the invention relates to the use of a metal complex, which has a given geometry in the region of the metal center in the electronic ground state and seeks a changed geometry in the electronically excited state and which is present at 100% in a micro-crystalline or crystalline structure (thus as pure solid, e.g. as a crystalline film), particularly a metal complex according to formula I or II, in a optoelectronic device.

In a preferred embodiment of the invention, the metal complex used has a ΔE(S₁−T₁)-value between the lowest excited singlet (S₁)— state and the triplet (T₁)-state below of smaller than 2500 cm⁻¹, preferably smaller than 1500 cm⁻¹, more preferably smaller than 1000 cm⁻¹, most preferably smaller than 500 cm⁻¹.

The emitting metal complex having a given geometry in the region of the metal center in electronic ground state can be chosen from a group consisting of mononuclear metal complexes and binuclear metal complexes. In the preferred embodiments of the invention, the metal complex is a copper complex, a gold complex or a silver complex. Preferably, the mononuclear metal complex is a complex according to formula I and the binuclear metal complex is a complex according to formula II, which are shown below.

The change in given geometry due to electronic excitation is in particular the change of a tetrahedral coordination towards square-planar coordination relating to a change with a tendency to planarization.

The electronically excited metal complex used in the invention and present in the composition preferably has an emission lifetime of at the most 20 preferably of at the most 10 μs. Furthermore, it is preferred that the metal complex shows an emission quantum yield of the solid of greater than 45%, preferably greater than 70%, particularly preferably greater than 90%.

### DETAILED DESCRIPTION OF THE INVENTION

### Singlet Harvesting

It is of particular importance to loosen the forbidden transition prohibition from the excited triplet state T₁ to the singlet state S₀ in order to develop emitter molecules with shortest possible emission decay times, yet high emission quantum yields. OLEDs using such emitters show a markedly diminished roll-off behavior of efficiency and provide for a longer operating life of the optoelectronic device.

Surprisingly, the object described above is met by the present invention by using emitter molecules that have particular electronic structures or singlet-triplet-energy differences and that show the singlet-harvesting effect. In FIG. 2a, a diagram of energy levels for transition metal complexes with spin orbit coupling that is either small or has only a small effect (e.g. metal complexes of the first or second period of the transition metals or also metal complexes with extensive ligand-centered triplet states of the third period) is depicted. The photo-physical electroluminescence properties of these molecules are described with reference to this diagram. Hole-electron recombination, as occurs, for example, in an optoelectronic element and optoelectronic device respectively, leads, on statistical average, to 25% occupation of the singlet state (1 singlet path) and to 75% occupation of the triplet state (3 triplet paths) that lie at ΔE₁(S₁−T₁) below. The excitation into the S₁ state relaxes due to the intersystem crossing (ISC) process, which generally is faster than 10⁻¹² s in transition metal organic complexes, into the T₁ state. The radiative emission lifetime of the triplet stat is very long for these metal complexes of the first period of the transition metals (e.g., 50 μs to 1000 μs or longer). Emitters exhibiting such long emission decay times are hardly suitable for application in OLEDs.

The disadvantages of the state of the art described above can be avoided by choosing metal complexes that have an energy difference ΔE(S₁−T₁) between the lowest excited singlet state (S₁) and the triplet state (T₁) below it, of smaller than 2500 cm⁻¹. This is illustrated by the energy level diagram shown in FIG. 2b. This energy difference is small enough to enable thermal repopulation of the S₁ state from the T₁ state according to a Boltzmann distribution, or according to the thermal energy k_{B}T.

Thus thermally activated light emission from the S₁-state can occur. This process proceeds according to equation (1):

Int(S₁→S₀)Int(T₁→S₀)=k(S₁)/k(T₁)exp(−ΔE(S₁−T₁)/k_{B}T) (1)

In this equation, Int(S₁→S₀)/Int(T₁→S₀) is the intensity ratio of the emissions from the S₁ state and the T₁ state. k_{B} is the Boltzmann constant and T the absolute temperature. k(S₁)/k(T₁) is the rate ratio of the (radiative) conversion processes to the electronic ground state S₀. For Cu(I)-complexes for example, this ratio is between 10² and 10⁴. Preferred in accordance with the invention are molecules having a rate ratio of about 10³ to 10⁵. ΔE represents the energy difference ΔE₂(S₁−T₁) according to FIG. 2b.

The process of thermal repopulation described herein opens up an emission channel via the singlet state S₁ from the populated triplet. Since the transition from the S₁ to the S₀ state is strongly allowed, the triplet excitation energy is obtained virtually completely as light emission via the singlet state. The smaller the energy difference ΔE, the more marked this effect is. Preference is therefore given to Cu(I)-complexes (and also Ag(I)- and Au(I)-complexes) having a ΔE=ΔE(S₁−T₁) value between the lowermost excited singlet state and the triplet state below it of less than 1500 cm⁻¹, preferably less than 1000 cm⁻¹, more preferably of less than 500 cm⁻¹.

This effect is to be illustrated by a numerical example. Given a typical energy difference of ΔE(S₁−T₁)=800 cm⁻¹, for room temperature applications (T=300K) with k_{B}T=210 cm⁻¹ and a rate ratio of 10³, an intensity ratio of the singlet to triplet emission according to equation (1) of approximately 20 is obtained. This means that the singlet emission process is dominant to an extreme degree for a molecule having these example values.

The emission lifetime of this example molecule also changes as a result. The thermal repopulation results in a mean lifetime τₐᵥ. This can be described by equation (2)

τₐᵥ≈(S₁)·exp(ΔE(S₁−T₁)/k_{B}T) (2)

In this equation, τ(S₁) is the fluorescence lifetime without repopulation and τₐᵥ is the emission lifetime, which is determined on opening of the repopulation channel by the two states T₁ and S₁ (see FIG. 2b). The other parameters have been defined above.

Equation (2) is again to be illustrated by a numerical example. For the assumed energy difference of ΔE(S₁−T₁)=800 cm⁻¹ and a decay time of the fluorescing S₁ state of 50 ns, an emission decay time (of the two states) of τₐᵥ=2 μs is obtained. This decay time is shorter than those of very good Ir(III) or Pt(II) triplet emitters known in the state of art.

In summary, using this singlet harvesting process for complexes, more particularly complexes according to formulas I an II described below it is thus possible in the ideal case to capture virtually all, i.e. a maximum of 100%, of the excitons and convert them to light via singlet emission. In addition, it is possible to shorten the emission decay time well below the value for pure triplet emitters of these complexes, which is generally a few hundred μs to ms. Therefore, the use according to the invention of the respective complexes is particularly suitable for optoelectronic devices such as OLEDs.

The complexes having the above-described properties, i.e. having a small singlet-triplet energy difference ΔE (S₁−T₁), are preferably described with the general formulas I and II given below. The electronic transitions that govern the optical properties of these complexes show a pronounced metal to ligand charge transfer character. This transition type correlates with a relatively small value of the quantum-mechanical exchange integral, which is known to a person of skill in the art. This results in the desired small energy difference ΔE(S₁−T₁).

The invention refers in another aspect to a method for selecting complexes, whose ΔE(S₁−T₁)-value between the lowest exited singlet state (S₁) and the triplet state (T₁) below it is smaller than 2500 cm⁻¹, preferably smaller than 1500 cm⁻¹, particularly preferred smaller than 1000 cm⁻¹, most preferred smaller than 500 cm⁻¹.

The determination of the ΔE(S₁−T₁) value can either be performed by quantum-mechanical calculations using computer programs known in the art (for example, using Turbomole programs executing TDDFT calculations with reference to CC2 calculations) or determined experimentally, as explained below.

The energy difference ΔE(S₁−T₁), more particularly of the complexes described by formulas I and II can be described as an approximation by quantum-mechanical means via the exchange integral multiplied by the factor 2. The value of the latter depends directly on the so-called charge-transfer-character under participation d-orbitals of the metal and the π*-orbitals of the ligands. This means that an electronic transition between the different molecular orbitals represents a metal-to-ligand charge transfer (CT) process. The smaller the overlap of the above-described molecular orbitals, the more marked is the electronic charge transfer character. This is then associated with a decrease in the exchange integral and hence a decrease in the energy difference ΔE(S₁−T₁). Due to these photo-physical (quantum-mechanical) properties, it is possible to achieve the energy differences according to the invention with ΔE(S₁−T₁) of less than 2500 cm⁻⁻¹ or less than 1500 cm⁻⁻¹ or less than 1000 cm⁻¹ or even less than 500 cm⁻¹.

The ΔE(S₁−T₁) value can be determined experimentally as follows:

For a given complex, the energy difference ΔE(S₁−T₁)=ΔE can be determined in a simple manner using the above-specified equation (1). A rearrangement gives:

ln {Int(S₁→S₀)/Int(T₁→S₀)}=ln {k(S₁)/k(T₁)}−(ΔE(S₁−T₁)/k_{B})(1/T) (3)

For the measurement of the intensities Int(S₁→S₀) and Int(T₁→S₀), it is possible to use any commercial spectrophotometer. A graphic plot of the (logarithmized) intensity ratios ln {Int(S₁→S₀)/Int(T₁→S₀)} measured at different temperatures against the reciprocal of the absolute temperature T generally gives a straight line. The measurement is conducted within a temperature range from room temperature (300K) to 77 K or to 4.2 K, the temperature being established by means of a cryostat. The intensities are determined from the (corrected) spectra, Int(S₁→S₀) and Int(T₁→S₀) representing, respectively, the integrated fluorescence and phosphorescence band intensities, which can be determined by means of the programs provided with the spectrophotometer. The respective transitions (band intensities) can be identified easily since the triplet band is of lower energy than the singlet band and gains intensity with falling temperature. The measurements are conducted in oxygen-free diluted solutions (approx. 10⁻² mol L⁻¹) or on thin films of the corresponding molecules or on films doped with the corresponding molecules. If the sample used is a solution, it is advisable to use a solvent or solvent mixture which forms glasses at low temperatures, such as 2-methyl-tetrahydrofuran, butyronitrile, toluene, ethanol or aliphatic hydrocarbons. If the sample used is a film, the use of a matrix having a much greater singlet and triplet energy than that of the metal complexes (emitter molecules) according to formulas I or II, for example, PMMA (polymethyl methacrylate), is suitable. This film can be applied from solution.

The slope of the straight line is −ΔE/k_{B}. With k_{B}=1.380·10⁻²³ JK⁻¹=0.695 cm⁻¹K⁻¹, it is possible to determine the energy separation directly.

A simple, approximate estimation of the ΔE(S₁−T₁) value can also be made by recording the fluorescence and phosphorescence spectra at low temperature (e.g. 77K or 4.2K using a cryostat). The ΔE(S₁−T₁) value then corresponds approximately to the energy difference between the high-energy slope flanks of the fluorescence and phosphorescence bands.

Another method for determining the ΔE(S₁−T₁)-value is through measuring the emission decay time with an instrument that is commercially available. Herein, the emission lifetime τₐᵥ is measured using a cryostat for the range between 4.2 K or, e.g., 20 K and 300 K. Using formula (4) and the emission lifetime measured at low temperature for the triplet state τ(T₁), a fit of the measured values can be performed according to formula (4), yielding the ΔE(S₁−T₁)-value. (Note: The τ(T₁)-value is often represented by the plateau that might be seen when the measured values are plotted. In case such a plateau is seen, cooling to 4.2 K is generally not necessary.)

$${τ}_{av } = \frac{3 + exp ( - \frac{Δ E ( {S}_{1} - {T}_{1} )}{{k}_{B} T} )}{\frac{3}{τ ( {T}_{1} )} + \frac{1}{τ ( {S}_{1} )} exp ( - \frac{Δ E ( {S}_{1} - {T}_{1} )}{{k}_{B} T} )} \qquad ( 4 )$$

The more pronounced the CT character of an organic molecule, the more the electronic transition energies change as a function of solvent polarity. Therefore, a strong polarity dependence of the emission energies provides an indication of small ΔE(S₁−T₁) values.

### Flexibilization of the Molecular Structure and the Immediate Surroundings

The four-coordinated complexes according to formula I and II have an almost tetrahedral geometry in the region of the metal center in the electronic ground state. In case of optical excitation or an excitation by a hole-electron recombination into a electronic state with distinct metal to ligand charge transfer character and the associated formal oxidation of the metal atom, considerably changes in the geometry of the complex towards square-planar coordination occur, i.e. towards a planarization of the molecule with regard to a metal center of formula I and/or both metal centers of formula II. This process lowers the energies of the emitting states. Due to the change in geometry of the excited state compared to the ground state, an increase of the Stokes-shift between absorption and emission results. Consequently, emission is shifted to longer wavelengths (e.g. blue to green or yellow to red) and the spectral width of the emission bands is increased (e.g. by 10 to 100 nm). In case the emission covers the spectral range of blue, green as well as red, a white light emission can also be generated. Examples for color changes are shown in FIG. 3 and illustrated in tables 1 to 6.

Another aspect of the invention is that the change in geometry, which results from the excitation process, can be controlled. This means that a small change in geometry leads to a likewise small shift of the emission colors and a comparatively small widening of the emission bands, so that the emitting behavior of the metal complex may correspond approximately to the one of the rigid solid or to the behavior in frozen solutions. Medium-sized changes in geometry, which are, for example, restricted by sterical hindrance, color shifts and widening of the emission bands of some ten nanometers are obtained, whereas in very soft environments of the emitting molecules (e.g. also in fluid solutions) very strong changes in geometry and thus great color changes (e.g. by 200 nm) and widening of the bands (e.g. up to 100 nm) may occur (see also the example given in FIG. 1).

Within the scope of the method for the increase of the Stokes-shift, the control of the possible extent of the change in geometry due to electronic excitation can be carried out according to the invention by means of two strategies, namely by intra-molecular substitution and/or changing the rigidity of the polymeric matrix, in which the metal complex is embedded:

### Intra-Molecular Substitution

By varying the steric bulk of the ligands, their substituents R, and/or their size (see formulas I and II) the molecular possible twists can be influenced within a wide range, but also largely suppressed. The extent of the possible distortions can, on the one hand, be determined by quantum mechanical calculations (e.g. using Turbomole or Gaussian programs under execution of DFT and TDDFT directions respectively). On the other hand, the shift and the widening of the emission bands can be determined experimentally. For this purpose, the emission behavior of a solid and afterwards of a solution is analyzed. Comparison of the emission spectra directly leads to the desired statement about the extent of the change of the emission bands

### Modification of the Rigidity of the Matrix

A high rigidity is existent when a crystalline solid is used (e.g. as 100% emitter material, for instance in an OLED). The examples given show (FIG. 3, table 1) that on this basis a blue-light emission is easily accessible.

In many applications, emitter molecules are doped in polymeric matrices, namely, for example, in concentrations of 2 to 20 weight percent. Such dopings are for example used in emission layers for efficient OLEDs. In case of doping, the individual environment of the emitter molecule determines whether the maximum possible change in geometry predetermined by the chemical structure of the complex can actually take place. In general, this individual environment in a given matrix is not identical for each emitter molecule. This means that the distribution of the embedding situations is very inhomogeneous. In other words, emitter complexes will be present in relatively small and rigid gaps for integration, but also (other) complexes will find a relatively large free space. This finally leads to a range of possibilities of changes in geometry. Consequently, ranges of color shifts and thus broadenings of emission bands will result, as desired.

The focus of a color shift and the width of the emission band connected with it is determined by the polymeric matrix used. This way, various size distributions of the gaps in the matrices and various rigidities can be achieved by variation and/or pre-treatment of the polymers. For example,—as is known to those skilled in the art—amorphous, soft polymers (e.g. polysiloxanes, polyethylene oxides) or medium-rigid (e.g. polymethyl metacrylates (PMMA), polycarbonates), but also very rigid polymers (e.g. polyphenylene oxides) can be used. The rigidity can also be significantly increased by using cross-linkable polymers, wherein the crosslinking is initiated by thermal or UV activation or by use of auto-catalysing emitter materials, i.e. the metal center present in the metal complex emitter serves simultaneously as catalyst, so that an auto-catalyzed crosslinking takes place.

One example for the dependency on the pre-treatment of the polymer is given. PMMA is a polymer, which is semi-crystalline in small areas. Through annealing (increase in temperature to approximately 70° C. to 90° C. and subsequent cooling) the crystalline areas grow and the matrix material becomes more rigid. This influences the occurring color shift compared to the dye emission. Said color shift can be reduced through annealing alone by several nm.

The rigidity of a polymeric matrix can generally be described by the glass transition temperature T_{g}. The lower this temperature is, the more flexible is the matrix and thus also the direct environment of the doped chromophor/emitter. T_{g} values are found in literature. (see, for example, B. Wolfgang Kaiser, “Kunststoffchemie für Ingenieure”, Carl Hanser Verlag, München 2006 and e.g. Hans-Georg Elias “Makromoleküle, Band 2: Physikalische Strukturen and Eigenschaften”, 6. Aufl., Wiley-VCH, Weinheim 2001, page 452 ff.)

Furthermore, as mentioned above, polymeric matrices are characterized by free spaces between the (very large) polymer molecules. The sizes and distributions of these free spaces vary with the type of polymer, pre-treatment and the temperature difference relative to T_{g}. Information about these properties are important for many technological areas (e.g. rates of drug release). Consequently, for more than five decades extensive investigations and classifications have been carried out (e.g. H. Fujita, Adv. Polym. Sci. 1961, 3, 1; D. Ehlich, H. Sillescu, Macromolecules 1990, 23, 1600; M. T. Cicerone, F. R. Blackburn, M. D. Ediger, Macromolecules 1995, 28, 8224). The degree (frequency and size) of free space can be correlated, for example, to measurable accessible diffusion coefficients of small molecules in the polymeric matrix (see, for example: D. Ehlich, H. Sillescu, Macromolecules 1990, 23, 1600; M. T. Cicerone, F. R. Blackburn, M. D. Ediger, Macromolecules 1995, 28, 8224). Polymeric matrices with a desired flexibility in the micro area of the doped emitter molecules can be named and provided accordingly.

### Metal Complexes (Emitter Molecules) Suitable for Color Shift

### Formula I and II

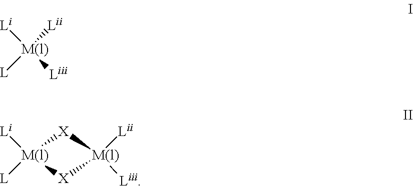

with

### M=Cu, Ag or Au

L-Lⁱⁱⁱ: suitable ligands, which are defined further below. The ligands can be same ore different. The ligands can either be monodentate ligands or connected with each other forming multidentate, in particular bidentate ligands. Formulas I and II comprise either four monodentate ligands or two bidentate ligands or one bidentate and two monodentate ligands. In particular mono- and bidentate phosphine and arsine ligands as well as ligands with at least one N-donor atom are used. The ligands may either be neutral or singly negatively charged.

X in formula II is a suitable bridge, as for example the anions Cl⁻, Br⁻, I⁻, SCN⁻, CN⁻, RS⁻, RSe⁻, R₂N⁻, R₂P⁻, R—C≡C⁻,

wherein

R=Alkyl (e.g. Me, Et, n-Pr, i-Pr, n-Bu, t-Bu, adamantyl), aryl (e.g. phenyl, tolyl, napthyl, C₆F₅), heteroaryl (e.g. furyl, thienyl, pyridyl, pyrimidyl), alkenyl (e.g. CR═CR″R′″), alkinyl (—C≡C—R′), —OR′, —NR′₂; R′, R″, R′″ are defined such as R and can also be H.

The alkyl, aryl, alkenyl and alkinyl rests can also be deuterated, halogenated or substituted in another way (e.g. with more alkyl, aryl, alkenyl and alkinyl functions).

The bridge may also be:

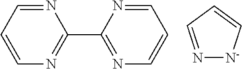 [SMILES: c1cnc(-c2ncccn2)nc1 ; c1cn[n-]c1]

Depending on the charge of the ligand the complexes may have the following charge: −1, 0 and +1. The charge is compensated by a suitable counter-ion.

As cations may be used: metal cations, particularly alkali metal, NH₄⁺, NR₄⁺, PH₄⁺, PR₄⁺, with R=alkyl (e.g. Me, Et, n-Pr, i-Pr, n-Bu, t-Bu, adamantyl), Aryl (e.g. phenyl, tolyl, napthyl, C₆F₅), heteroaryl (e.g. furyl, thienyl, pyridyl, pyrimidyl), alkenyl (e.g. CR═CR″R′″), alkinyl (—C≡C—R′), —OR′, —NR′₂.

As anions may be used: halides, PF6⁻, BF₄⁻, AsF₆⁻, SbF₆⁻, ClO₄⁻, NO₃⁻, BR₄⁻,

with R=alkyl (e.g. Me, Et, n-Pr, i-Pr, n-Bu, t-Bu, adamantyl), aryl (e.g. phenyl, tolyl, napthyl, C₆F₅), heteroaryl (e.g. furyl, thienyl, pyridyl, pyrimidyl), alkenyl (e.g. CR═CR″R′″), alkinyl (—C≡C—R′), —OR′, —NR′₂. R′, R″ and R′″ are defined such as R and can also be H.

### Definition of Ligands (L to Lⁱⁱⁱ in Formulas I and II)

### Neutral Monodentate Phosphine Ligands

R₃P with the same of different R=Alkyl (e.g. Me, Et, Pr, i-Pr, n-Bu, t-Bu, adamantyl), aryl (e.g. phenyl, tolyl, napthyl, C₆F₅), heteroaryl (e.g. furyl, thienyl, pyridyl, pyrimidyl), alkenyl (e.g. CR═CR″R′″), alkinyl (—C≡C—R′), —OR′, —NR′₂.

R′, R″, R′″ are defined such as R and can also be H.

The alkyl, aryl, alkenyl and alkinyl rests can also be deuterated, halogenated or substituted in another way (e.g. with more alkyl, aryl, alkenyl and alkinyl functions).

### Neutral Bidentate Phosphine Ligands

The ligands shown below are bonded via the phosphorous atom to the metal ion of the metal complex. R is an organic rest, in particular R=alkyl (e.g. Me, Et, n-Pr, i-Pr, n-Bu, t-Bu, adamantyl), aryl (e.g. phenyl, tolyl, napthyl, C₆F₅), heteroaryl (e.g. furyl, thienyl, pyridyl, pyrimidyl), alkenyl (e.g. CR═CR″R′″), alkinyl (—C≡C—R′), —OR′, —NR′₂. R′, R″ and R′″ are defined such as R and can also be H.

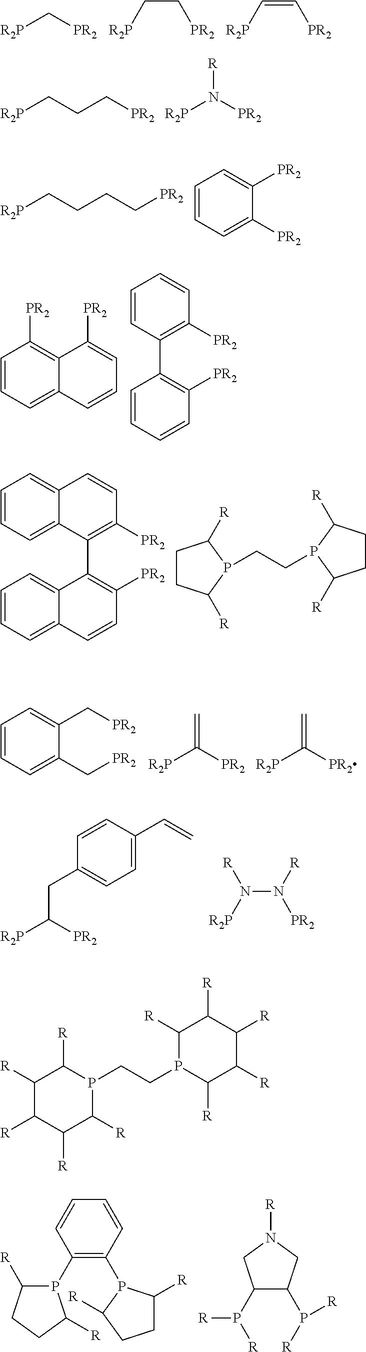

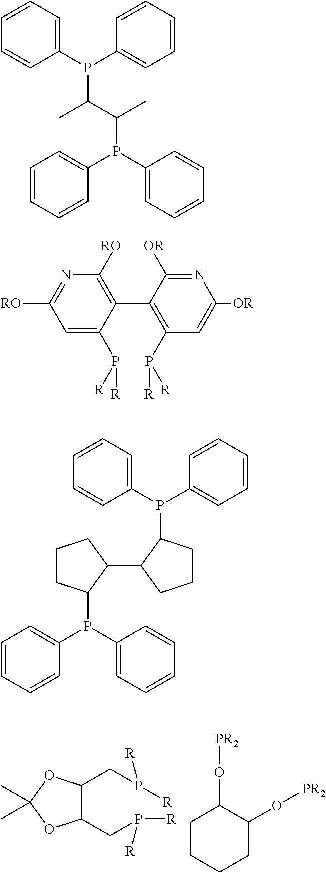

The rests R in the structures can be the same or different.

### Charged Phosphine Ligands

The charged phosphine ligands may be, for example, the compounds shown below. The rest R is an organic substituent and is defined as described for rest R for the neutral monodentate phosphine ligands. The rests R in the structures can be the same or different. One or also both phosphorous atoms may be oxidized to a phosphine oxide (R₂R′P═O).

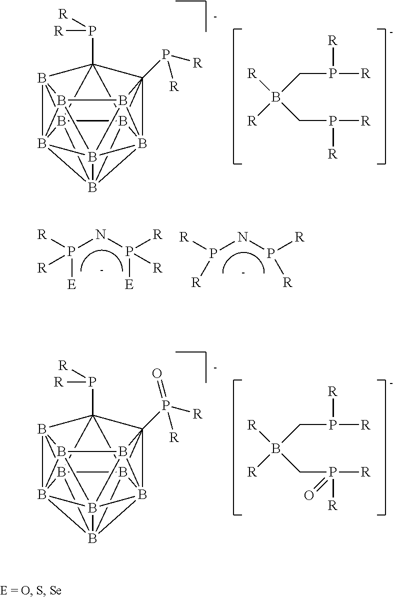

The following examples shall illustrate the generic ligand structures mentioned above:

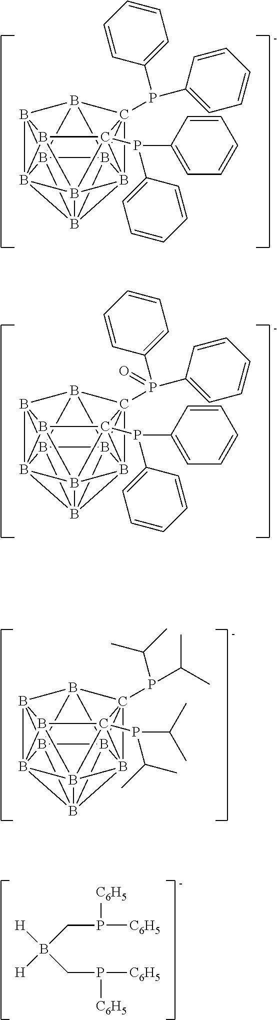

The phosphorous atom can be replaced by an arsenic atom in all structures of the phosphine ligands shown.

### Neutral Monodentate N-Donor Ligands

Neutral monodentate N-donor ligands are either nitriles R—C≡N or imines, in particular heterocyclic imines of the following structure:

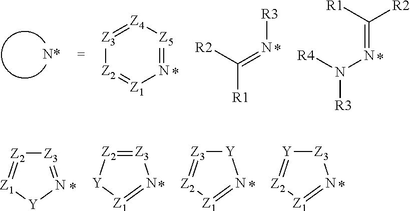

wherein Z1-Z5=N or CR(X)
with R(X)=organic group.

These organic groups R(X) as well as R, R1, R2 and R3 can be identical or independent from each other and be chosen from the group comprising: hydrogen, halogen and groups, which are bound via oxygen- (—OR), nitrogen- (—NR₂) or silicon atoms (—SiR₃), as well as alkyl-, aryl-, heteroaryl- und alkenyl-groups and accordingly substituted alkyl-, aryl-, heteroaryl- and alkenyl-groups with substituents such as halogens or deuterium, alkyl groups and further generally known donor and acceptor groups such as tertiary amines, carboxylates and esters thereof, and CF₃-groups. The organic groups may also lead to annulated ring systems.

X=sequential number.

### Neutral Bidentate N-Donor Ligands

Particularly preferred are α-diimine ligands, which advantageously have the following structure:

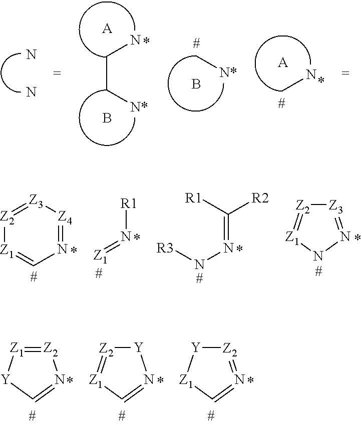

α-Diimine ligands, as used herein, can consist of five- or six-membered rings, which parts Z1-Z4 are either the fragments CR(X) or N.

With R(X)=organic rest. These organic groups R(X) as well as R, R1, R2 and R3 can be identical or independent from each other and be chosen from the group comprising: hydrogen, halogen and groups, which are bound via oxygen- (—OR), nitrogen- (—NR₂) or silicon atoms (—SiR₃), as well as alkyl-, aryl-, heteroaryl- und alkenyl-groups and accordingly substituted alkyl-, aryl-, heteroaryl- and alkenyl-groups with substituents such as halogens or deuterium, alkyl groups and further generally known donor and acceptor groups such as tertiary amines, carboxylates and esters thereof, and CF₃-groups. The organic groups may also lead to annulated ring systems.

X=sequential number,

Y can be either NR, O, or S.

This definition also includes the possibility, that A and B do not form a cycle and are open-chained. (“#” indicates the atom, which is bound to the second unit. “*” indicates the atom, which makes the complex bond). The units A and B may also be connected by an additional bridge, so that a new aromatic or aliphatic cycle is formed.

The above structural description of α-diimine ligands is illustrated by the following examples.

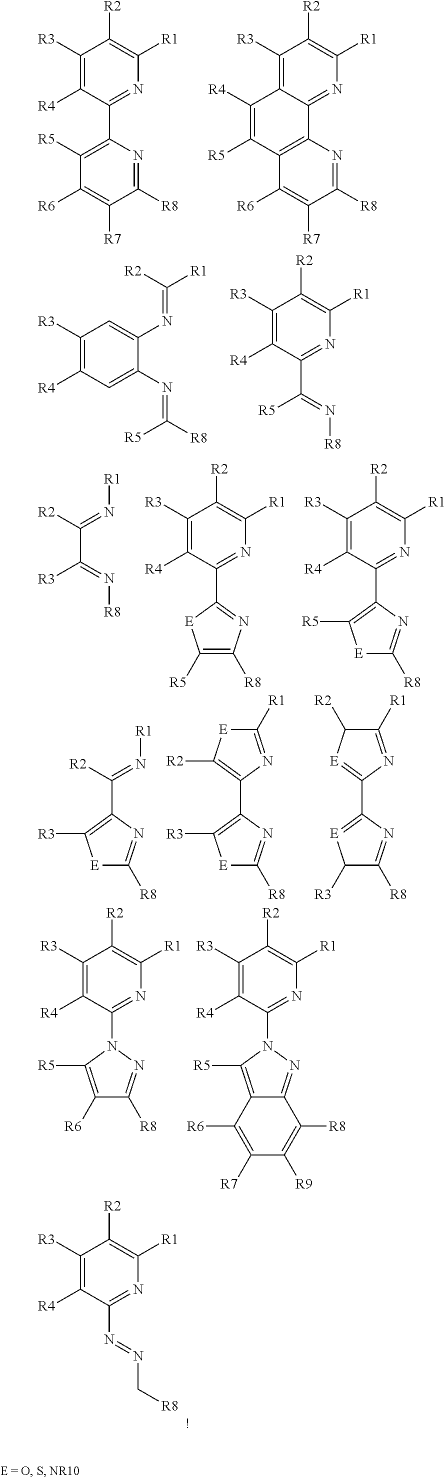

R(X), as well as R1-R10 are each organic groups R, which can be identical or independent from each other. These organic groups can be chosen from the group comprising: hydrogen, halogen and groups, which are bound via oxygen- (—OR), nitrogen- (—NR₂) or silicon atoms (—SiR₃), as well as alkyl-, aryl-, heteroaryl- und alkenyl-groups and accordingly substituted alkyl-, aryl-, heteroaryl- and alkenyl-groups with substituents such as halogens or deuterium, alkyl groups and further generally known donor and acceptor groups such as tertiary amines, carboxylates and esters thereof, and CF₃-groups. The organic groups may also lead to annulated ring systems.

It is crucial that the substituents, which are adjacent to the coordinated N-atomes (thus R1 and R8), are sterically less demanding groups, so that sufficient flexibility of the metal complexes remains. Sterically less demanding are in particular substituents which consist of only one atom (e.g. H, Cl, Br, I), as well as methyl and ethyl groups. Larger substituents lead to a strong stiffening of the complexes and strongly reduce the flexibility of the molecules respectively even prevent the corresponding effect. Particularly preferred are substituents, whose space requirement and size respectively do not considerably exceed the one of a methyl group.

### Singly Negatively Charged Bidentate N-Donor Ligands

Anionic Ligands N—B—N

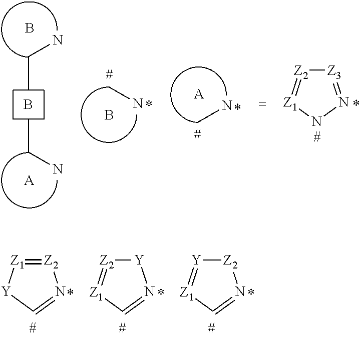

wherein Z1-Z3=N or CR(X),
with R(X)=organic rest. These organic groups R(X) can be identical or independent from each other and be chosen from the group comprising: hydrogen, halogen and groups, which are bound via oxygen- (—OR), nitrogen- (—NR₂) or silicon atoms (—SiR₃), as well as alkyl-, aryl-, heteroaryl- und alkenyl-groups and accordingly substituted alkyl-, aryl-, heteroaryl- and alkenyl-groups with substituents such as halogens or deuterium, alkyl groups and further generally known donor and acceptor groups such as tertiary amines, carboxylates and esters thereof, and CF₃-groups. The organic groups may also lead to annulated ring systems.

X=sequential number

Y═O, S or NR.

The bridge B means the fragment R′₂B, e.g. H₂B, Ph₂B, Me₂B, (R₂N)₂B etc. (with Ph=phenyl, Me=methyl);

“*” indicates the atom, which makes the complex bond
“#” indicates the atom, which is bound to the second unit via B.

These ligands will be referred to as N—B—N. The singly negatively charged N-donor ligand may be one of the molecules shown below:

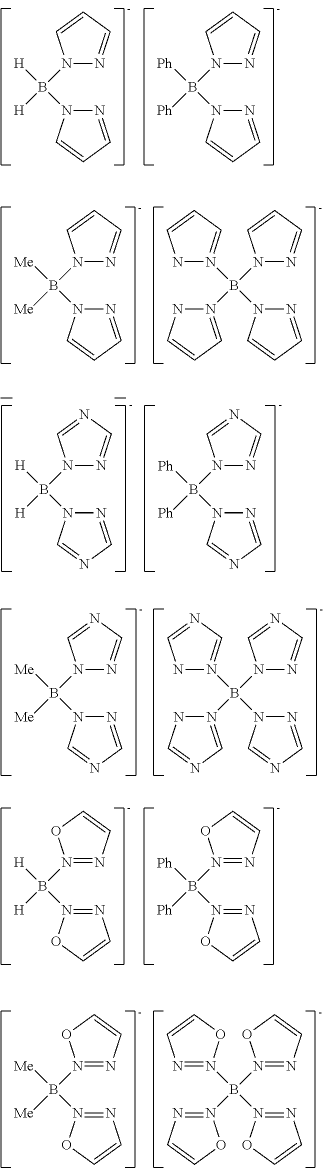

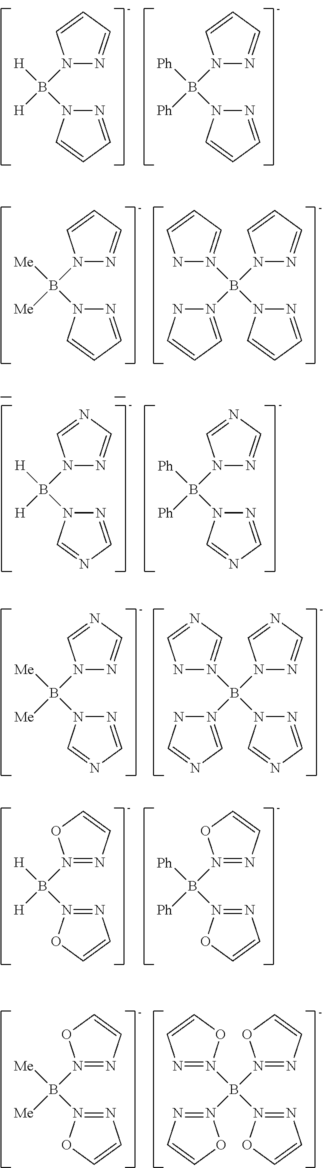

Anionic Ligands N—B′—N and NN

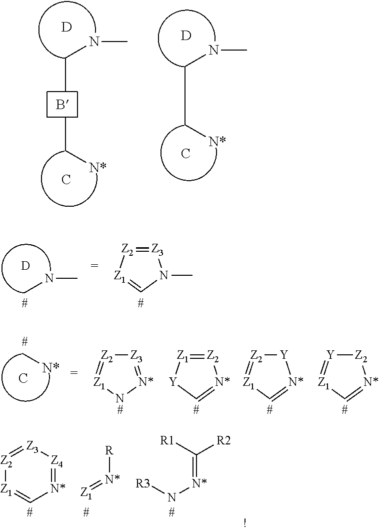

wherein
Z1-Z4=N or fragment CR(X),
with R(X)=organic rest. These organic groups R(X) as well as R, R1 and R2 can be identical or independent from each other and be chosen from the group comprising: hydrogen, halogen and groups, which are bound via oxygen- (—OR), nitrogen- (—NR₂) or silicon atoms (—SiR₃), as well as alkyl-, aryl-, heteroaryl- and alkenyl-groups and accordingly substituted alkyl-, aryl-, heteroaryl- and alkenyl-groups with substituents such as halogens or deuterium, alkyl groups and further generally known donor and acceptor groups such as tertiary amines, carboxylates and esters thereof, and CF₃-groups. The organic groups may also lead to annulated ring systems.

X=sequential number

Y is either O, S or NR.

The bridge B′ is an neutral bridge, such as —CH₂—, —CR₂—, —SiR₂—, —NH—, —NR—, —O—, or —S—; (R is again generally an organic group and is defined as described above for the neutral monodentate phosphine ligands.)

“*” indicates the atom, which makes the complex bond
“#” indicates the atom, which is directly bound to the second unit or bound via B to the second unit.

Nitrogen ligands comprising the bridge B′ are abbreviated as N—B′—N and nitrogen ligands, which do not comprise this bridge, are abbreviated as NN.

The following examples shall illustrate this type of ligand:

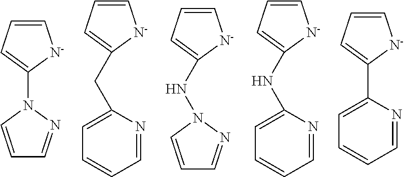 [SMILES: c1c[n-]c(-n2cccn2)c1 ; c1ccc(Cc2ccc[n-]2)nc1 ; c1c[n-]c(Nn2cccn2)c1 ; c1ccc(Nc2ccc[n-]2)nc1 ; c1ccc(-c2ccc[n-]2)nc1]

Neutral Bidentate N̂P-Ligands

The neutral bidentate NAP ligands can be, for example, compounds in the form of N*nE, with E=phosphanyl/arsenyl/antimonyl rest in the form of R₂E (R=alkyl, aryl, alkoxyl, phenoxyl, amide); N*=sp2-hybridized N-atom, which is part of an aromatic group (e.g. pyridyl, pyrimidyl, pyridazinyl, triazinyl, oxazolyl, thiazolyl, imidazolyl, pyrazole, isoxazole, isothiazole, 1,2,4-triazoles, 1,2,4-oxadiazoles, 1,2,4-thiadiazoles, tetrazoles, 1,2,3,4-oxatriazoles and/or 1,2,3,4-thiatriazoles, etc.); “∩”=at least one carbon atom, which is also part of the aromatic group, wherein the carbon atom is adjacent to the sp2-hybridized N-atom as well as to the phosphorous, arsenic or antimony atom. Preferably, the ligand N*∩E is one of the following ligands

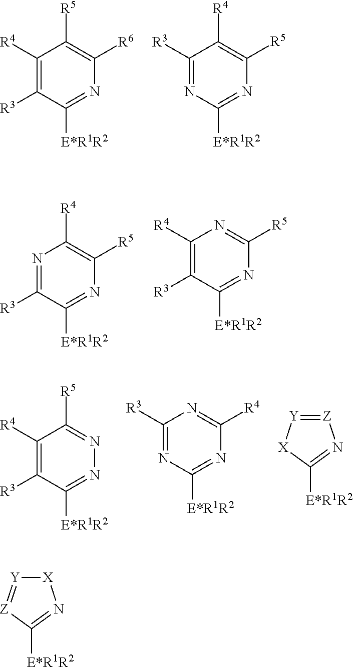

X═NR³, Y═CR⁴, Z═CR⁵: 2E*R¹R²-1R³-4R⁵-5R⁴-1H-Imidazole X═NR³, Y═CR⁴, Z═CR⁵: 3E*R¹R²-1R³-4R⁵-5R⁴-1H-Pyrazole
X═NR³, Y═N, Z═CR⁴: 5E*R¹R²-1R³-3R⁴-1H-1,2,4-Triazole X═NR³, Y═N, Z═CR⁴: 4E*R¹R²-2R³-5R⁴-2H-1,2,3-Triazole
X═NR³, Y═CR⁴, Z═N: 3E*R¹R²-4R³-5R⁴-4H-1,2,4-Triazole X═NR³, Y═CR⁴, Z═N: 3E*R¹R²-1R³-5R⁴-1H-1,2,4-Triazole
X═NR³, Y═N, Z═N:5E*R¹R²-1R³-1H-Tetrazole X═NR³, Y═N, Z═N: 5E*R¹R²-2R³-2H-Tetrazole
X═O, Y═CR³, Z═CR⁴: 2E*R¹R²-4R⁴-5R³—Oxazole X═O, Y═CR³, Z═CR⁴: 3E*R¹R²-4R⁴-5R³-Isoxazole
X═O, Y═N, Z═CR³: 5E*R¹R²-3R³-1,2,4-Oxadiazole X═O, Y═N, Z═CR³: 3E*R¹R²-4R³-1,2,5-Oxadiazole
X═O, Y═CR³, Z═N: 2E*R¹R²-5R³-1,3,4-Oxadiazole X═O, Y═CR³, Z═N: 3E″R¹R²-5R³-1,2,4-Oxadiazole

### X═O, Y═N, Z═N: 5E*R¹R²-1,2,3,4-Oxatriazole X═O, Y═N, Z═N: 4E*R¹R²-1,2,3,5-Oxatriazole

X═S, Y═CR³, Z═CR⁴: 2E*R¹R²-4R⁴-5R³-Thiazole X═S, Y═CR³, Z═CR⁴: 3E*R¹R²-4R⁴-5R³-Isothiazole
X═S, Y═N, Z═CR³: 5E*R¹R²-3R³-1,2,4-Thiadiazole X═S, Y═N, Z═CR³: 3E*R¹R²-4R³-1,2,5-Thiadiazole
X═S, Y═CR³, Z═N: 2E*R¹R²-5R³-1,3,4-Thiadiazole X═S, Y═CR³, Z═N: 3E*R¹R²-5R³-1,2,4-Thiadiazole

### X═S, Y═N, Z═N:5E*R¹R²-1,2,3,4-Thiatriazole X═S, Y═N, Z═N: 4E*R¹R²-1,2,3,5-Thiatriazole

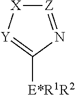

### X═NR³, Y═CR⁴, Z═CR⁵: 4E*R¹R²-1R³-2R⁵-5R⁴-1H-Imidazole

### X═NR³, Y═N, Z═CR⁴: 3E*R¹R²-1R³-5R⁴-1H-1,2,4-Triazole

### X═NR³, Y═CR⁴, Z═N: 4E*R¹R²-1R³-5R⁴-1H-1,2,3-Triazole

### X═NR³, Y═N, Z═N: 5E*R¹R²-2R³-2H-Tetrazole

### X═O, Y═CR³, Z═CR⁴: 4E*R¹R²-2R⁴-5R³—Oxazole

### X═O, Y═N, Z═CR³: 3E*R¹R²-5R³-1,2,4-Oxadiazole

### X═O, Y═CR³, Z═N:4E*R¹R²-5R³-1,2,3-Oxadiazole

### X═O, Y═N, Z═N: 4E*R¹R²-1,2,3,5-Oxatriazole

### X═S, Y═CR³, Z═CR⁴: 4E*R¹R²-2R⁴-5R³-Thiazole

### X═S, Y═N, Z═CR³: 3E*R¹R²-5R³-1,2,4-Thiadiazole

### X═S, Y═CR³, Z═N: 4E*R¹R²-5R³-1,2,3-Thiadiazole

### X═S, Y═N, Z═N: 4E*R¹R²-1,2,3,5-Thiatriazole

with

### E*=P, As or Sb,

### X═NR³, O or S,

### Y═CR³, CR⁴ or N,

### Z═CR⁴, CR⁵ or N,

R¹-R⁵ can be, independently from each other, hydrogen, halogen or substituents, which are bound via oxygen- (—OR), nitrogen- (—NR₂) or silicon atoms (—SiR₃), as well as alkyl (also branched and cyclic), aryl, heteroaryl, alkenyl, alkinyl groups and accordingly substituted alkyl (also branched and cyclic) aryl, heteroaryl and alkenyl groups with substituents such as halogens or deuterium, alkyl groups (also branched and cyclic) and further generally known donor and acceptor groups such as amines, carboxylates and esters thereof, and CF₃-groups. R3-R5 may optionally lead to annulated ring systems.

Preferably the metal complex comprises at least one, for cross-linking with the polymeric matrix preferably two or more anchor groups. The anchor groups can be located at any position of the organic ligand of the metal complex, preferably not in ortho position to the atom coordinating to the metal center.

The substituents of the structures N*∪E of the copper(I) complexes, in particular the anchor groups, can be located at any position of the structure. In particular, in one embodiment of the invention the position of the substituent, is possible in ortho, meta and/or para position to the heteroatom, which coordinates to the Cu ion. A substitution in meta and/or para position is preferred.

### FIGURES

FIG. 1: Basic structure of an OLED, not drawn to scale.

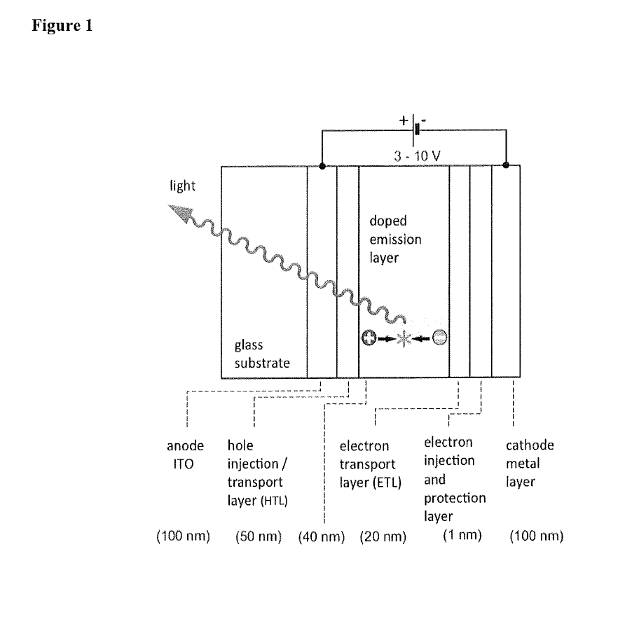

FIG. 2: a Illustration of the electro luminescence behavior for transition metal complexes with a spin orbit coupling that is small or has a small effect and comparatively high energy difference ΔE₁(S₁−T₁) i.e., for example, greater than 3000 cm⁻¹ between the lowest excited triplet state (T₁) and the singlet state (S₁) above it. The value of τ(T₁) is an example. b Diagram to illustrate the electro luminescence behavior for metal complexes with comparatively small energy difference ΔE₂(S₁−T₁) i.e., for example, smaller than 2500 cm⁻¹ between the lowest excited triplet state (T₁) and the singlet state (S₁) above it. An example for b is shown in FIG. 3. τ₁(ISC) and τ₂(ISC) represent inter system crossing times.

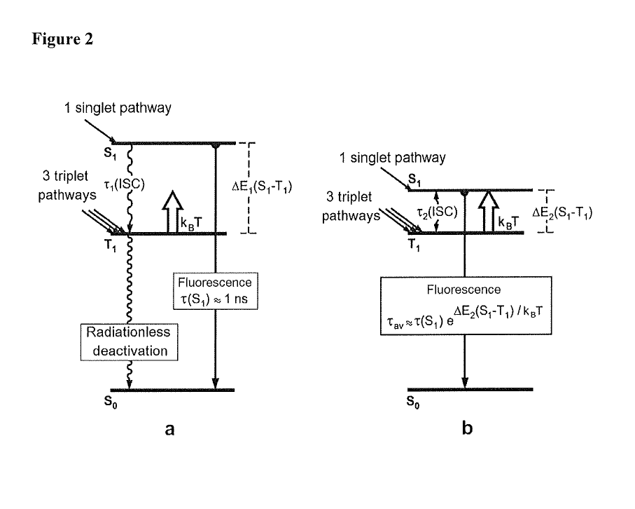

FIG. 3 shows the absorbance spectrum and emission spectra of Cu(POP)(pz₂BH₂).

FIG. 4 shows a general scheme for the linking of organic metal complexes (first reactant) with monomers, oligomers or polymers (second reactant), which each comprise a corresponding anchor group, which makes the cross-linking of the metal complex in the polymer matrix possible. The reaction product is labelled as composit.

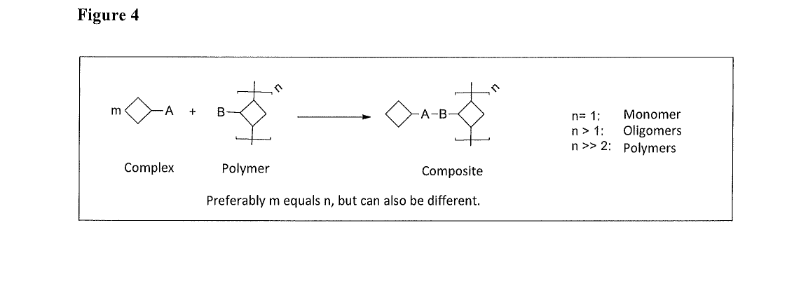

FIG. 5 shows selected examples for anchor groups of a first and a second anchor group species (each arranged in rows). The anchors groups shown opposite to each other can, bound on the one hand to the metal complex and on the other hand to the second reactant, form a covalent bond between the reactants and thus link and immobilize the metal complex. First and second anchor group species are addressed here as anchor A and anchor B. Depending on the use, the anchor A shown here can represent the first or the second anchor group species and the anchor B can represent accordingly the second or the first anchor group species.

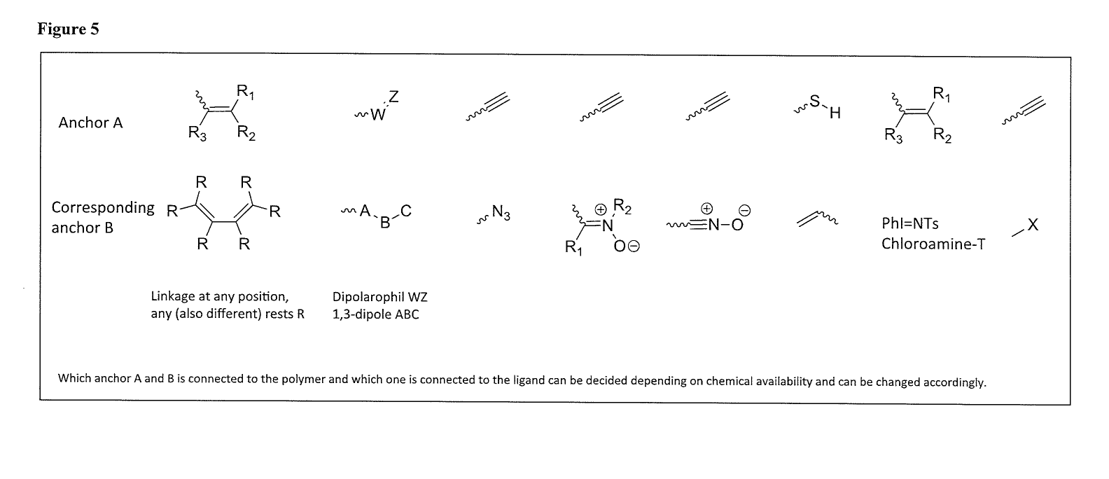

### EXAMPLES

### Examples of Formula I

### Example A Cu(POP)(pz₂BH₂)

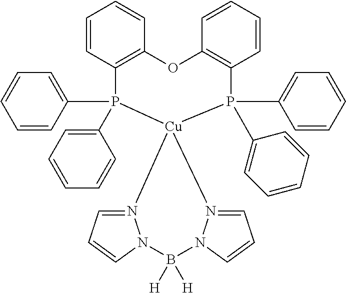

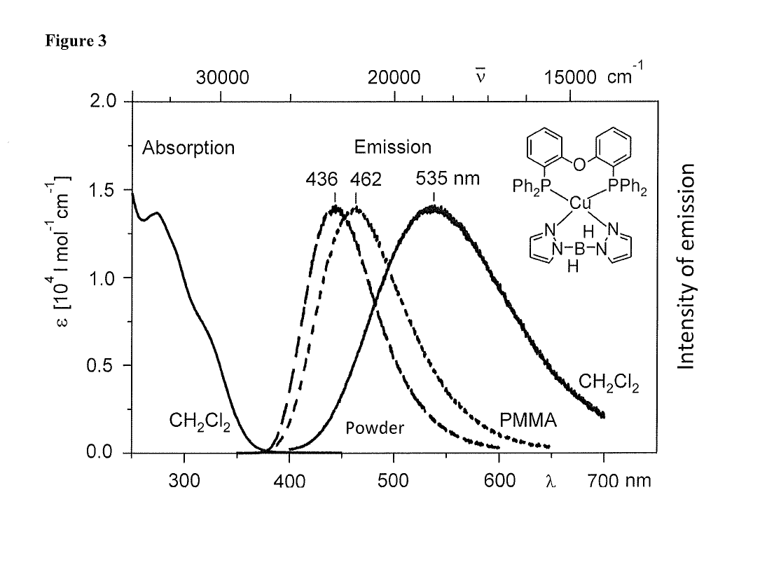

FIG. 3 shows the absorption and emission spectra of Cu(POP)(pz₂BH₂). These have been recorded at room temperature. Due to the embedding in a polymeric matrix (specified in the figure) a strong color shift of the emission results.

Absorption and emission in CH₂Cl₂: c=5×10⁻⁵ mol/L. Emission in PMMA: c≈0.5 weight percent. Emission from powder with c=100%.

TABLE 1
Emission data of Cu(POP)(pz₂BH₂) in different matrices

| | Powder^{a} | PMMA^{a} | CH₂Cl₂^{b} |
|---|---|---|---|
| Emission maximum λₘₐₓ [nm] | 436 | 462 | 535 |
| Emission lifetime τ [μs] | 20 | 22 | 1.3 |
| Quantum yield φ_{PL} [%] | 45 | 35 | |
| CIE color coordinates^{c} | 0.15; 0.11 | 0.17; 0.21 | 0.35; 0.47 |

^{a}Measured under N₂ atmosphere.
^{b}Measured after degassing.
^{c}These color coordinates are generally used for the description of the visual color impression (e.g. see T. Smith, J. Guild; Trans. Opt. Soc.1931/1932, 33, 73).

From studies of the temperature dependency of the emission lifetime the following values for the powder can be determined by using formula (4): ΔE(S₁−T₁)=1300 cm⁻⁻¹; τ(S₁)=30 ns; τ(T₁)=600 μs, τₐᵥ=20 μs. These data prove the appearance of the singlet-harvesting effect for Cu(POP)(pz₂BH₂).

### Example B Cu(POP)(pz₂ Bph₂)

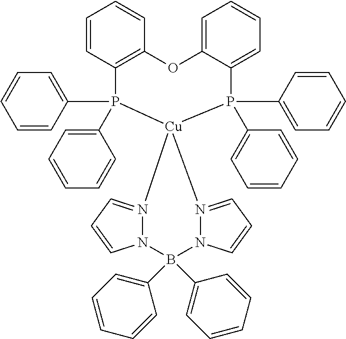

TABLE 2
Emission data of Cu(POP)(pz₂Bph₂) in solid and in CH₂Cl₂

| | Powder^{a} | CH₂Cl₂^{b} |
|---|---|---|
| Emission maximum λₘₐₓ [nm] | 468 | 498 |
| Emission lifetime τ [μs] | 13 | 1.8 |
| Quantum yield φ_{PL} [%] | 90 | ≈10 |
| CIE color coordinates^{c} | 0.16; 0.22 | 0.25; 0.39 |

^{a}Measured under N₂ atmosphere.
^{b}Measured after degassing.
^{c}These color coordinates are generally used for the description of the visual color impression (e.g. see T. Smith, J. Guild; Trans. Opt. Soc.1931/1932, 33, 73).

The emission lifetime was also measured at T=77K. The value for the powder is 475 μs. With a value of φ_{PL}=90% at T=300K the existence of the Singlet-Harvesting effect can be concluded because of the very strong increase of the lifetime by cooling.

### Example C Cu(POP)(pz₄B)

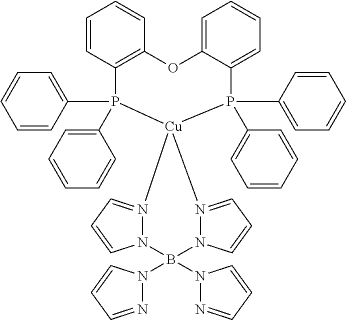

TABLE 3
Emission data of Cu(POP)(pz₄B) in different matrices

| | Powder^{a} | PMMA^{a} | CH₂Cl₂^{b} |
|---|---|---|---|
| Emission maximum λₘₐₓ [nm] | 451 | 457 | 500 |
| Emission lifetime τ [μs] | 22 | 24 | 0.5 |
| Quantum yield φ_{PL} [%] | 90 | 30 | 2 |
| CIE color coordinates^{c} | 0.14; 0.11 | 0.17; 0.18 | 0.26; 0.38 |

^{a}Measured under N₂ atmosphere.
^{b}Measured after degassing
^{c}These color coordinates are generally used for the description of the visual color impression (e.g. see T. Smith, J. Guild; Trans. Opt. Soc.1931/1932, 33, 73).

The emission lifetime was also measured at T=77K. The values are 450 us (powder) and 680 μs (complex in PMMA) respectively. Because of the very strong increase of the lifetime by cooling, the existence of the Singlet-Harvesting effect can be concluded.

The compounds [Au(dppb)₂]BF₄ (λₘₐₓ=490 nm, φ_{PL}=90%) and [Ag(dppb)₂]NO₃ (λₘₐₓ=445 nm) show blue powder emissions in a manner known. The emission is shifted, for example, for [Ag(dppb)₂]NO₃ in methanol to λₘₐₓ=680 nm. With an appropriate broad color shift area the generation of white light is possible when embedding the molecules in polymeric matrices.

### Examples of Formula II

### Example D Cu₂Br₂(PPh₃)₂(py)₂

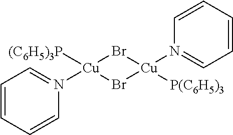

TABLE 4
Emission data of Cu₂Br₂(PPh₃)₂(py)₂ in solid and in PMMA

| | Powder^{a} | PMMA^{a} |
|---|---|---|
| Emission maximum λₘₐₓ [nm] | 485 | 517 |
| Emission lifetime τ [μs] | 19 | 12 |
| Quantum yield φ_{PL} [%] | 70 | 10 |

^{a}Measured under N₂ atmosphere.

The emission lifetime at T=2 K (measured in powder) is 630 μs. Because of the very strong increase of the lifetime by cooling, the existence of the Singlet-Harvesting effect can be concluded.

### Example E Cu₂Br₂(PPh₃)₂(4-MeO-py)₂

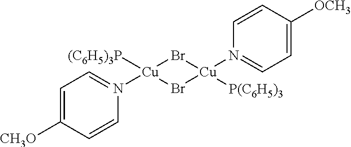

TABLE 5
Emission data of Cu₂Br₂(PPh₃)₂(4-MeO-py)₂ in different matrices

| | Powder^{a} | PMMA^{a} |
|---|---|---|
| Emission maximum λₘₐₓ [nm] | 450 | 490 |
| Emission lifetime τ [μs] | 7 | 6 |
| Quantum yield φ_{PL} [%] | 30 | |

^{a}Measured under N₂ atmosphere.

### Example F Cu₂Br₂(PPh₃)₂(4-tBu-py)₂

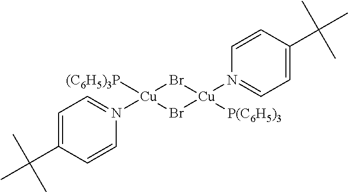

TABLE 6
Emission data of Cu₂Br₂(PPh₃)₂(4-tBu-py)₂ in different matrices

| | Powder^{a} | PMMA^{a} |
|---|---|---|
| Emission maximum λₘₐₓ [nm] | 465 | 505 |
| Emission lifetime τ [μs] | 17 | 11 |
| Quantum yield φ_{PL} [%] | 70 | <10 |

^{a}Measured under N₂ atmosphere.

The emission lifetime at T=2 K (measured in powder) is 650 μs. Because of the very strong increase of the lifetime by cooling, the existence of the Singlet-Harvesting effect can be concluded.

### Example G Cu₂I₂(Ph₂P(4-Mepy))₃,

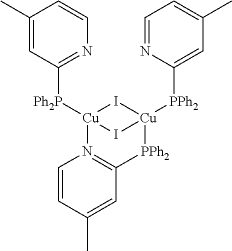

TABLE 7
Emission data of Cu₂Br₂(PPh₃)₂(4-tBu-py)₂ in different matrices

| | Powder^{a} | Film^{a} | CH₂Cl₂^{b} | PMMA^{a} | PS^{a} | PEG^{a} |
|---|---|---|---|---|---|---|
| Emission | 523 | 545 | 577 | 550 | 541 | 560 |
| maximum | | | | | | |
| λₘₐₓ [nm] | | | | | | |
| Quantum | 90 | 37 | 3 | 46 | 51 | 53 |
| yield | | | | | | |
| φ_{PL} [%] | | | | | | |
| CIE color | 0.32; | 0.38; | | 0.37; | 0.37; | 0.33; |
| coordinates | 0.52 | 0.51 | | 0.50 | 0.46 | 0.52 |

^{a}Measured under air atmosphere.
^{b}Measured after degassing.

By embedding the Cu(I) complex into different polymeric matrices different strong color shift of the emission results, which can be customized and adjusted by choosing different rigid polymeric matrices.

### Example H Cu₂I₂(Ph₂P(4-butinylpy))₃,

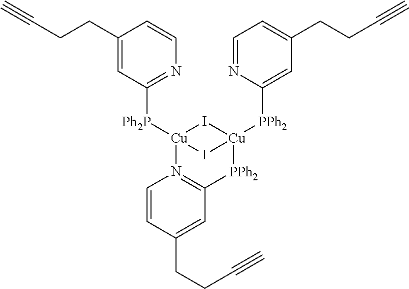

TABLE 7
Emission data of Cu₂Br₂(PPh₃)₂(4-tBu-py)₂ in different matrices

| | Powder^{a} | CH₂Cl₂^{b} | PMMA^{a} | PS^{a} | GAP | PS-Azid |
|---|---|---|---|---|---|---|
| Emission | 549 | 587 | 548 | 543 | 541 | 545 |
| maximum | | | | | | |
| λₘₐₓ [nm] | | | | | | |
| Quantum | 68 | 2 | 15 | 30 | | |
| yield | | | | | | |
| φ_{PL} [%] | | | | | | |
| CIE color | 0.38; | | 0.35; | 0.39; | | |
| coordinates | 0.52 | | 0.47 | 0.51 | | |

^{a}Measured under air atmosphere.
^{b}Measured after degassing.

By embedding the Cu(I) complex into different polymeric matrices, different strong color shift of the emission result, which can be customized and adjusted by choosing different rigid polymeric matrices. By use of linkable polymers such as GAP (glycidyl azide polymer) the rigidity of the matrix can be highly increased, wherein the crosslinking can be initiated by use of auto-catalysing crosslinking methods, i.e. the metal center present in the metal complex emitter serves as a catalyst, so that a auto-catalyzed crosslinking takes place. Exemplary for an auto-catalyzed crosslinking reaction the copper-catalyzed click reaction between a terminal or activated alkine as first click group and an azide as second click group has been used in this case. Since the metal complex emitter comprises at least two, in this example three alkine units, which is referred to herein also as first anchor groups, the formation of a multidimensional network occurs by auto-catalyzed reaction with a second reactant, which comprises at least two complementary azide units, which is referred to herein as second anchor groups. During this reaction, the metal complex is cross-linked in the forming multi-dimensional network, i.e. at least two bonds of the metal complex to multi-dimensional network formed from the second reactant, which is in this example the glycidyl azide polymer with n bonds, are formed. This may be in its simplest form a ladder-like (two-dimensional) structure, in which two strings of the network are linked by at least one metal complex emitter, which forms with each of the strings at least one covalent bond. Moreover, complicated three-dimensional networks, which include metal complex emitters that are cross-linked by a variable number of network strings are possible as product of this reaction. Thus, the cross-linked metal complex emitter is immobilized in the multi-dimensional network and fixed and stabilized with regard to its change in geometry.

It is known that a change of geometry at the emitter complex by excitation from the ground state to the first excited state leads to greater shifts of the energy potentials and to higher possibilities for non-radiative relaxation processes. Therefore, the geometry of the excited state should not differ from that of the ground state. Thus, the regional/sterical stabilisation of emitters achieved with the invention leads to an increase in efficiency.

Due to the anchor groups for the linking click-reactions that are present in the periphery of the ligands, the possible movement of the ligands of the metal complexes, e.g. emitter complexes, to each other is strongly limited. Thus, the complexes are fixed and stabilized. The transition probabilities for non-radiative processes are reduced by rotation and twisting in contrast to “free” complexes: The emission quantum yields are increased. Simultaneously, the fixation leads to maximal utilization of the energetic gap between the ground state and the first excited state. Hereby, in comparison to the “free”, i.e. not cross-linked complex, a blue shift of the emission spectrum can take place, because the population of rotational and vibrational states is less probable and the energy difference between the ground state and the first excited state (direct vertical alignment of the potential curves, cf. Franck-Condon-principle) is maximized. It is possible to shift the emission of a given, free, i.e. not cross-linked emitting metal complex, in direction of or into the blue spectral range by means of immobilization.

The method comprises at least the following steps: A mixture of a first reactant in form of a organic metal complex emitter and a second reactant in form of a polymer, thus a means for the immobilization of the metal complex, is deposited on a solid support. The metal complex is cross-linked into the forming multi-dimensional network during the applied auto-catalyzed reaction of the first reactant with the second reactant. The formation of the cross-linking is preferably carried out at higher temperature, preferably between 80° C. to 120° C. The application of a mixture of both reactants on a solid support can be carried out by all means known in the art, in particular by inkjet-printing, dipping, spin coating, slot-die coating, or knife coating.

After application on a glass slide using a doctor blade apparatus (all other known printing or coating methods such as spin coating, slot-die coating or inkjet-printing, for example, are also possible) in a thin layer and curing by heating to 100° C. for 30 minutes, this layer became stabilized and insoluble. Using this method, multilayer arrangements, which otherwise need orthogonal solvents or photochemical curing steps for implementation, can be easily realized. In addition, this cross-linking provides for a stabilization and fixation of the geometric structure of the metal complexes, preventing a movement of the ligands and thus a change in structure of the excited molecules and effectively inhibiting a reduction in efficiency due to non-radiative relaxation pathways.

As proven by the shown experimental data, the metal complexes described herein can also be used in 100% as emitters, i.e. without the presence of a polymeric matrix. Then they are present in a micro-crystalline structure and can feature in particular high emission quantum yields. This behavior is particularly favorable in comparison to the one of many other known solids (100% materials). In the latter case, distinct quenching of emission generally occurs. As known to the person skilled in the art, this is based on the fact that processes of the radiationless energy transfer (Förster-Dexter-transfer) from one excited molecule to the neighboring molecule and further to the next neighboring molecule etc. can take place. As a result, the interference points/impurities that are always present are reached, at which quenching of the emission can occur. Moreover, such energy transfer processes can lead to an excitation of the molecule, which is in spatial vicinity of another already excited molecule, whereby a pronounced triplet-triplet annihilation can result. Thereby, a strong decrease of the emission quantum yield can also result. Due to small changes in geometry, which can, in particular, occur for complexes according to formulas I and II even in a solid, and the reduction of energy of the excited state affiliated with the changes in geometry, the resonance condition necessary for the energy transfer is no longer present. For this reason, quenching processes as described above can hardly occur and a high emission quantum yield is reached.

According to the invention, in one embodiment the polymeric matrix and accordingly its rigidity are chosen such that a slight distortion of the complex can occur. Thereby, as described above, radiationless energy transfer can be significantly reduced or inhibited. Consequently, high emission and accordingly electroluminescence quantum yields can also be achieved at high emitter doping concentrations (above 30 and preferably above 50 weight %, copper complex/polymeric material). High emitter concentrations then permit in an OLED application an increase in efficiency at high brightness and accordingly at high current density (reduction of the roll-off of the efficiency with increasing current density).

Preferably the emission quantum yield in the solid is at least 45% (e.g. Cu(POP)(pz₂BH₂), preferably at least 70% (e.g. Cu₂Br₂(PPh₃)₂(py)₂), particularly preferably at least 90% (e.g. Cu(POP)(pz₄B) and Cu(POP)(pz₂ Bph₂)).

Accordingly, the invention also relates to metal complexes, particularly metal complexes according to formula I and II, in which a slight distortion occurs in the excited state in comparison to the geometry of the ground state, whereby the radiationless energy transfer between the emitter complexes is reduced or inhibited.

1-24. (canceled)

25. A method for shifting an emission wavelength of a metal complex emitting at a given wavelength to wavelengths greater than the given wavelength, wherein the metal complex comprises:
a ΔE(S₁−T₁)-value between a lowest excited singlet (S₁)-state and a triplet (T₁)-state below the lowest excited singlet (S₁)-state of smaller than 2500 cm⁻¹; and
a given geometry in a region of the metal center in the electronic ground state, wherein the metal complex seeks a changed geometry in an electronically excited state, and the method comprises the step of embedding the metal complex into a polymeric matrix to allow a change of the given geometry.

26. The method according to claim 25, wherein:
the metal complex as a first reactant comprises at least two anchor groups of a first anchor group species for covalently embedding the metal complex into the polymeric matrix;
a second reactant for formation of the polymeric matrix comprises at least one anchor group of a second anchor group species for the formation of the polymeric matrix; and
cross-linking of the metal complex into the polymeric matrix is achieved through a reaction of each of the at least two anchor groups of the metal complex with a second anchor group of the second reactant.

27. The method according to claim 25, wherein the metal complex is a mononuclear metal complex according to 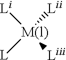
or a binuclear metal complex according to

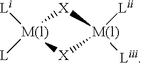

28. The method according to claim 27, wherein the metal complex includes an anchor group for covalently embedding the metal complex into the polymeric matrix.

29. The method according to claim 25, wherein the change in the given geometry is a change of a tetrahedral coordination towards a square-planar coordination.

30. The method according to claim 25, wherein the metal complex has an emission lifetime of at most 20 μs in the electronically excited state.

31. The method according to claim 25, wherein the metal complex has an emission quantum yield as a solid of larger than 30%.

32. The method according to claim 25, wherein a shift of the emission wavelength by embedding is at least 10 nm.

33. The method according to claim 25, wherein an emission spectrum of the metal complex is broadened by at least 10 nm by embedding the metal complex into the polymeric matrix.

34. The method according to claim 25, wherein the embedded metal complex emits white light.

35. The method according to claim 25, wherein the method is used on a metal complex in in an optoelectronic device chosen from the group consisting of an organic light emitting diode (OLED), a light-emitting electrochemical cell (LEEC), an OLED-sensor, an organic solar cell (OSC), an organic field-effect transistor, an organic laser, an organic diodes, an organic photo diode and a down conversion systems.

36. The method according to claim 35, wherein the OLED-sensor is at least one of a gas sensor and a vapor sensor not hermetically screened from the outside.

37. A composition, comprising:
an emitting metal complex having a ΔE(S₁-TO-value between a lowest excited singlet (S₁)-state and a triplet (T₁)-state below the lowest excited singlet (S₁)-state of smaller than 2500 cm⁻¹, and having a given geometry in a region of the metal center in the electronic ground state, wherein the metal complex seeks a changed geometry in an electronically excited state; and
a polymeric matrix, wherein the metal complex is embedded into the polymeric matrix so that the given geometry of the metal complex is changed by electronic excitation.

38. The composition according to claim 37, wherein the metal complex and the polymeric matrix are linked via complementary anchor groups.

39. The composition according to claim 37, wherein the metal complex is a mononuclear metal complex according to 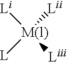
or a binuclear metal complex according to

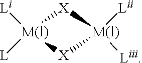

40. The composition according to claim 37, wherein the change in the given geometry is a change of a tetrahedral coordination towards square-planar coordination.

41. The composition according to claim 37, wherein the metal complex has an emission lifetime of at most 20 μs in the electronically excited state.

42. The composition according to claim 37, wherein the metal complex has an emission quantum yield in a solid of larger than 30%.

43. An optoelectronic device comprising the composition according to claim 37, wherein the optoelectronic device is chosen from the group consisting of an organic light emitting diode (OLED), a light-emitting electrochemical cell (LEEC), an OLED-sensor, an organic solar cell (OSC), an organic field-effect transistor, an organic laser, an organic diodes, an organic photo diode and a down conversion systems.

44. The optoelectronic device according to claim 43, wherein the OLED-sensor is at least one of a gas sensor and a vapor sensor not hermetically screened from the outside.

45. A metal complex, comprising:
a ΔE(S₁−T₁)-value between a lowest excited singlet (S₁)-state and a triplet (T₁)-state below the lowest excited singlet (S₁)-state of smaller than 2500 cm⁻¹;
a given geometry in a region of the metal center in the electronic ground state; and
a micro-crystalline or crystalline structure, wherein:
the metal complex is a mononuclear metal complex according to 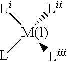
or a binuclear metal complex according to

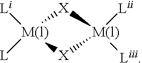

46. The metal complex according to claim 45, wherein the metal complex comprises an anchor group for covalent embedding of the metal complex into a polymeric matrix.

47. The metal complex according to claim 45, wherein the metal complex seeks a changed geometry in an electronically excited state, and the metal complex is embedded into a polymeric matrix so that the given geometry of the metal complex is changed by electronic excitation.

48. The metal complex according to claim 47, wherein the change in the given geometry is a change of a tetrahedral coordination towards square-planar coordination.

49. The metal complex according to claim 45, wherein the metal complex has an emission lifetime of at most 20 μs in an electronically excited state.

50. The metal complex according to claim 45, wherein the metal complex has an emission quantum yield in a solid of larger than 45%.

51. The metal complex according to claim 50, wherein the metal complex is in an optoelectronic device.

52. The metal complex according to claim 51, wherein the optoelectronic device is chosen from the group consisting of an organic light emitting diode (OLED), a light-emitting electrochemical cell (LEEC), an OLED-sensor, an organic solar cell (OSC), an organic field-effect transistor, an organic laser, an organic diodes, an organic photo diode and a down conversion systems.
